(19) United States
(12) Patent Application Publication
(10) Pub. No.: US 2026/0160822 A1
(43) Pub. Date: Jun. 11, 2026

(54) BATTERY MANAGEMENT DEVICE, BATTERY MANAGEMENT METHOD, AND NON-TRANSITORY STORAGE MEDIUM

(71) Applicant: TOYOTA JIDOSHA KABUSHIKI KAISHA, Toyota-shi (JP)

(72) Inventors: Ryo MANO, Nisshin-shi (JP); Yoshiaki Kikuchi, Toyota-shi (JP); Yuji Nishi, Nagoya-shi (JP); Hiroki Tashiro, Nisshin-shi (JP); Keisuke Ishikawa, Nagakute-shi (JP)

(73) Assignee: TOYOTA JIDOSHA KABUSHIKI KAISHA, Toyota-shi (JP)

(21) Appl. No.: 19/392,610

(22) Filed: Nov. 18, 2025

(30) Foreign Application Priority Data
Dec. 10, 2024 (JP) 2024-215842

(51) Int. Cl. G01R 31/389; G01R 31/392; G01R 31/396; H01M 10/0525; H01M 10/42; H01M 10/48

(52) U.S. Cl. CPC G01R 31/389; G01R 31/392; G01R 31/396; H01M 10/425; H01M 10/482; H01M 10/486; H01M 10/0525; H01M 2010/4271

(57) ABSTRACT

A battery management device includes a high-frequency signal supply unit configured to apply a high-frequency signal having a frequency equal to or higher than 0.1 MHz to a first battery cell having a low battery temperature among a plurality of battery cells constituting a lithium-ion secondary battery, an impedance detection unit configured to detect a real part of alternating current impedance of the first battery cell to which the high-frequency signal is applied, and a determination unit configured to determine whether Li has been precipitated in the lithium-ion secondary battery based on the real part of the alternating current impedance of the first battery cell.

### CROSS-REFERENCE TO RELATED APPLICATION

This application claims priority to Japanese Patent Application No. 2024-215842 filed on Dec. 10, 2024. The disclosure of the above-identified application, including the specification, drawings, and claims, is incorporated by reference herein in its entirety.

### BACKGROUND

### 1. Technical Field

The present disclosure relates to a battery management device, a battery management method, and a non-transitory storage medium.

### 2. Description of Related Art

To prevent degradation of performance of a lithium-ion secondary battery, it is desired to suppress precipitation of Li (lithium) metal (hereinafter, Li precipitation) in the lithium-ion secondary battery. However, a method for detecting Li precipitation in the lithium-ion secondary battery in a non-destructive manner has not been known.

To address this, as disclosed in Japanese Unexamined Patent Application Publication No. 2022-108602 (JP 2022-108602 A), the inventors have developed a method for detecting a real part of alternating current impedance of a lithium-ion secondary battery using a high-frequency signal and calculating an amount of Li precipitation in the lithium-ion secondary battery based on a difference between a current value and an initial value of the real part of the alternating current impedance.

### SUMMARY

By the way, Li precipitation progresses more as charging electric power is larger, and thus, allowable charging electric power is set for each type of the lithium-ion secondary battery to suppress Li precipitation. Here, there is variability (for example, standard deviation σ) in a progress speed of Li precipitation in the lithium-ion secondary battery for each product even in the same type. In the lithium-ion secondary battery in the related art, allowable charging electric power in each type is set (fixed) at excessively low such that Li precipitation does not progress, for example, in a product included in a range of ±6σ, which causes a problem that a charging period becomes long.

Thus, the inventors have developed a method for decreasing allowable charging electric power in accordance with whether Li precipitation detected using the method disclosed in JP 2022-108602 A has occurred. The method makes it possible to set higher allowable charging electric power to such a degree that Li precipitation does not progress upon start of use and shorten a charging period.

However, if a circuit that applies a high-frequency signal is provided at each of a plurality of battery cells constituting the lithium-ion secondary battery, the number of circuits and cost increase.

The present disclosure has been made in view of the above-described background and provides a battery management device, a battery management method, and a non-transitory storage medium that can implement efficient charging of a lithium-ion secondary battery at low cost.

A battery management device according to a first aspect of the present disclosure includes a high-frequency signal supply unit configured to apply a high-frequency signal having a frequency equal to or higher than 0.1 MHz to a first battery cell having a low battery temperature among a plurality of battery cells constituting a lithium-ion secondary battery, an impedance detection unit configured to detect a real part of alternating current impedance of the first battery cell to which the high-frequency signal is applied, and a determination unit configured to determine whether Li has been precipitated in the lithium-ion secondary battery based on the real part of the alternating current impedance of the first battery cell.

In the battery management device according to the first aspect of the present disclosure, the high-frequency signal supply unit may be configured to further apply the high-frequency signal to a second battery cell having a higher battery temperature than a battery temperature of the first battery cell among the plurality of battery cells. The impedance detection unit may be configured to further detect a real part of alternating current impedance of the second battery cell. The determination unit may be configured to determine whether Li has been precipitated in the lithium-ion secondary battery based on the real part of the alternating current impedance of the first battery cell and the real part of the alternating current impedance of the second battery cell detected at the same battery temperature.

In the battery management device according to the first aspect of the present disclosure, the determination unit may be configured to determine whether Li has been precipitated in the lithium-ion secondary battery based on a degree of change of the real part of the alternating current impedance of the first battery cell at a certain battery temperature and a degree of change of the real part of the alternating current impedance of the second battery cell at the certain battery temperature.

The battery management device according to the first aspect of the present disclosure may further include a multiplexer configured to switch a connection destination of an electronic circuit that functions as the impedance detection unit between the first battery cell and the second battery cell.

The battery management device according to the first aspect of the present disclosure may further include a temperature detection unit configured to detect a battery temperature of each of the plurality of battery cells and set the first battery cell based on a detection result.

A battery management method according to a second aspect of the present disclosure includes applying a high-frequency signal having a frequency equal to or higher than 0.1 MHz to a first battery cell having a low battery temperature among a plurality of battery cells constituting a lithium-ion secondary battery, detecting a real part of alternating current impedance of the first battery cell to which the high-frequency signal is applied, and determining whether Li has been precipitated in the lithium-ion secondary battery based on the real part of the alternating current impedance of the first battery cell.

A non-transitory storage medium according to a third aspect of the present disclosure stores instructions that are executable by a computer and that cause the computer to perform functions including applying a high-frequency signal having a frequency equal to or higher than 0.1 MHz to a first battery cell having a low battery temperature among a plurality of battery cells constituting a lithium-ion secondary battery, detecting a real part of alternating current impedance of the first battery cell to which the high-frequency signal is applied, and determining whether Li has been precipitated in the lithium-ion secondary battery based on the real part of the alternating current impedance of the first battery cell.

According to the present disclosure, it is possible to provide a battery management device, a battery management method, and a non-transitory storage medium that can implement efficient charging of a lithium-ion secondary battery.

### BRIEF DESCRIPTION OF THE DRAWINGS

Features, advantages, and technical and industrial significance of exemplary embodiments of the present disclosure will be described below with reference to the accompanying drawings, in which like signs denote like elements, and wherein:

FIG. 1 is a block diagram illustrating a configuration example of a battery management system according to the present disclosure;

FIG. 2 is a view indicating a relationship between an SOH of a secondary battery and a degree of change of a real part Z of alternating current impedance when a high-frequency signal of 1 MHz is supplied to the secondary battery;

FIG. 3 is a view indicating a relationship between a frequency of an alternating current signal to be supplied to the secondary battery and a real part of alternating current impedance detected from the secondary battery;

FIG. 4 is a view indicating a relationship between the frequency of the alternating current signal to be supplied to the secondary battery and the real part of the alternating current impedance detected from the secondary battery;

FIG. 5 is a flowchart exemplifying operation of a battery management device according to the present disclosure;

FIG. 6 is a block diagram illustrating a configuration example of the battery management system according to the present disclosure;

FIG. 7 is a block diagram illustrating a configuration example of the battery management system according to the present disclosure;

FIG. 8 is a flowchart exemplifying operation of the battery management device according to the present disclosure; and

FIG. 9 is a block diagram illustrating a configuration example of the battery management system according to the present disclosure.

### DETAILED DESCRIPTION OF EMBODIMENTS

Specific embodiments to which the present disclosure is applied will be described in detail below with reference to the drawings. However, the present disclosure is not limited to the following embodiments. Further, for clearer description, the following description and drawings are simplified as appropriate.

### First Embodiment

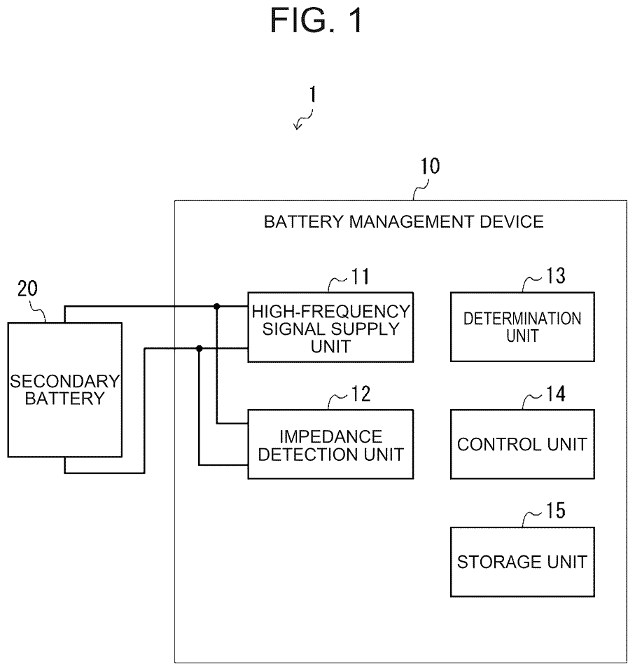

FIG. 1 is a block diagram illustrating a configuration example of a battery management system 1 according to a first embodiment. As illustrated in FIG. 1, the battery management system 1 includes a battery management device 10, and a secondary battery 20 managed by the battery management device 10.

The secondary battery 20, which is a lithium-ion secondary battery, is constituted with a cell stack including a plurality of stacked battery cells and a case accommodating the cell stack.

Each battery cell includes a positive electrode, a negative electrode, and an ion transmission medium that is provided between the positive electrode and the negative electrode and conducts carrier ions. A separator may be further provided between the positive electrode and the negative electrode. As the separator, resin such as polyethylene and polypropylene is used.

As a positive-electrode active material, for example, a sulfide including a transition metallic element, an oxide including lithium and a transition metallic element, or the like, is used. Specifically, as the positive-electrode active material, a lithium-manganese composite oxide having a basic composition formula of Li₍₁₋ₓ₎MnO₂ (where 0<x<1), Li₍₁₋ₓ₎Mn₂O₄, or the like, a lithium-cobalt composite oxide having a basic composition formula of Li₍₁₋ₓ₎CoO₂, or the like, a lithium-nickel composite oxide having a basic composition formula of Li₍₁₋ₓ₎NiO₂, or the like, a lithium-nickel-cobalt-manganese composite oxide having a basic composition formula of Li₍₁₋ₓ₎NiₐCo_{b}Mn_{c}O₂ (where a +b+c=1), or the like, is used. Note that materials including other elements in the above-described basic composition formulas may be used as the positive-electrode active material. As a current collector of the positive electrode, for example, aluminum (Al), or the like, is used.

As a negative-electrode active material, for example, a composite oxide including lithium, a carbon material, or the like, is used. Specifically, as the negative-electrode active material, an inorganic compound such as lithium, a lithium alloy, and a tin compound, a carbon material that can occlude and discharge lithium ions, a composite oxide including a plurality of elements, a conductive polymer, or the like, is used. While examples of the carbon material to be used as the negative-electrode active material can include cokes, glassy carbons, graphite, non-graphitizable carbons, pyrolytic carbons, carbon fibers, and the like, graphite such as artificial graphite and natural graphite is preferably used. Further, examples of the composite oxide to be used as the negative-electrode active material can include a lithium-titanium composite oxide and a lithium-vanadium composite oxide, and the like. As a current collector of the negative electrode, for example, copper (Cu), or the like, is used.

The ion transmission medium is used as, for example, an electrolyte by dissolving supporting salt. As the supporting salt, for example, lithium salt such as LiPF₆ and LiBF₄ is used. As a solvent of the electrolyte, for example, one of carbonates, esters, ethers, nitriles, furan, sulfolane, and dioxolane, or a mixture of some of them is used. Examples of the carbonates can include circular carbonates such as ethylene carbonate, propylene carbonate, vinylene carbonate, butylene carbonate, and chloroethylene carbonate, chain carbonates such as dimethyl carbonate, ethylmethyl carbonate, diethyl carbonate, ethyl-n-butyl carbonate, methyl-t-butyl carbonate, di-i-propyl carbonate, and t-butyl-i-propyl carbonate, and the like. Alternatively, as the ion transmission medium, a solid ion-conducting polymer, an inorganic solid electrolyte, a mixed material of an organic polymer electrolyte and an inorganic solid electrolyte, an inorganic solid powder bonded by an organic binder, or the like, may be used.

The battery management device 10 performs charging management of the secondary battery 20 to be managed. For example, the battery management device 10 detects whether Li has been precipitated in the secondary battery 20 in a non-destructive manner and performs feedback control of allowable charging electric power (upper limit of charging electric power) Pa for the secondary battery 20 based on a detection result.

The battery management device 10 includes a high-frequency signal supply unit 11, an impedance detection unit 12, a determination unit 13, a control unit 14, and a storage unit 15.

The high-frequency signal supply unit 11 supplies a high-frequency signal to a first battery cell among a plurality of battery cells constituting the secondary battery 20. The first cell has a low battery temperature among the plurality of battery cells constituting the secondary battery 20. For example, the battery temperature of the first cell may be the lowest among battery temperatures of the plurality of battery cells. The battery temperature of the first cell may be lower than a representative value (for example, an average value, a median value) of the battery temperatures of the plurality of battery cells.

The first battery cell may be set in advance through experiment or simulation. For example, there is a case where a battery temperature of the battery cell on an outer side closer to the case is lower in terms of heat dissipation. Further, there is a case where a battery temperature of the battery cell provided at a position separate from a heat source existing in an environment in which the secondary battery 20 is disposed or separate from a heat source existing inside the case of the secondary battery 20 is low. The secondary battery 20 can be utilized in a vehicle drive system, a home energy supply system, and the like.

By the way, in the secondary battery 20, Li metal is precipitated on an electrode surface of each battery cell as a result of charging being repeated. Li precipitation progresses more as charging electric power is made larger to increase a charging speed, and degrades a state of health (SOH) of the secondary battery 20. Note that the SOH of the secondary battery 20 refers to a ratio of current capacity when initial capacity of the secondary battery 20 is set as 100%. It is therefore desirable to set to the secondary battery 20, allowable charging electric power Pa as high as possible with which charging can be efficiently performed in a charging period as short as possible while suppressing Li precipitation.

Here, when an alternating current signal (high-frequency signal) having a frequency that is too high for diffusion, response, and movement of lithium ions to follow in each battery cell of the secondary battery 20 is supplied to the secondary battery 20, a current of the high-frequency signal flows along an edge of a conductor of each battery cell by a skin effect. In other words, the current of the high-frequency signal flows on an electrode surface of each battery cell on which Li is likely to be precipitated by a skin effect. Further, also when Li metal is put into a float state as a result of being electrically cut off from the negative electrode after the Li precipitation, a current flows on the Li metal by inductive coupling and electric field coupling. Thus, when Li is not precipitated from an initial state, a value of a real part Z of alternating current impedance does not change, and as an amount of Li precipitation becomes larger, electric conductivity of an electrode surface of each battery cell becomes higher, and thus, the value of the real part Z of the alternating current impedance becomes smaller. Here, many currents concentrate on the Li metal with high conductivity, and thus, a magnetic field changes around an Li precipitation region, and an eddy current occurs as a result of this. While this eddy current causes a loss in a current collector foil and a conductive portion of the electrode, a loss as a whole battery is reduced. Thus, as the amount of Li precipitation becomes larger, change of the magnetic field becomes larger, and the eddy current increases as a result of this, and thus, the value of the real part Z becomes smaller. Thus, the amount of Li precipitation in the secondary battery 20 can be calculated from the value of the real part Z of the alternating current impedance detected from the secondary battery 20 to which the high-frequency signal is supplied. If the amount of Li precipitation is known, the SOH of the secondary battery 20 can be also estimated.

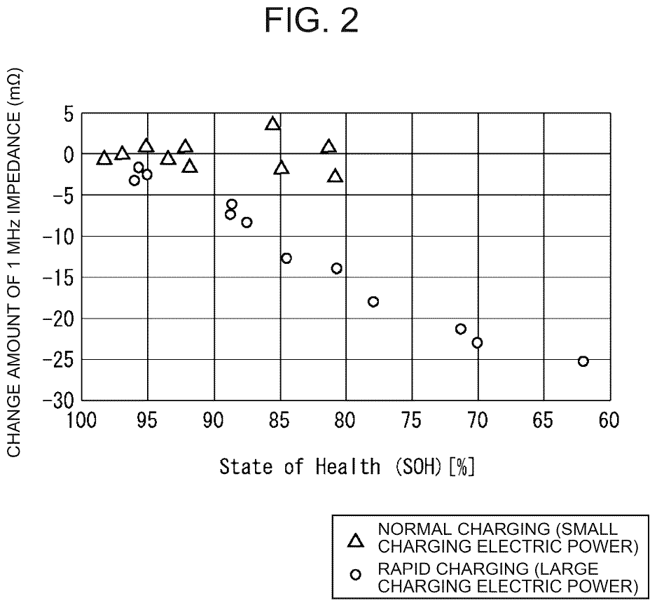

FIG. 2 is a view indicating a relationship between the SOH of the secondary battery 20 and a change amount (difference between a detection value and an initial value) of the real part Z of the alternating current impedance when a high-frequency signal of 1 MHz is supplied to the secondary battery 20. As indicated with a triangle mark in FIG. 2, in a case of normal charging with small charging electric power, the amount of Li precipitation is small even if charging is repeated, and thus, the change amount of the real part Z of the alternating current impedance remains small (that is, the detection value of the real part Z of the alternating current impedance is maintained at a high value) even if degradation of the SOH progresses due to other factors. In contrast, as indicated with a circle mark in FIG. 2, in a case of rapid charging with large charging electric power, the amount of Li precipitation increases as a result of charging being repeated, and thus, degradation of the SOH progresses, and the change amount of the real part Z of the alternating current impedance becomes large (that is, the detection value of the real part Z of the alternating current impedance becomes low). Note that when degradation of the battery due to Li precipitation is dominant among factors of degradation of the battery, the amount of Li precipitation can be derived from the SOH. Alternatively, the SOH can be derived from the amount of Li precipitation.

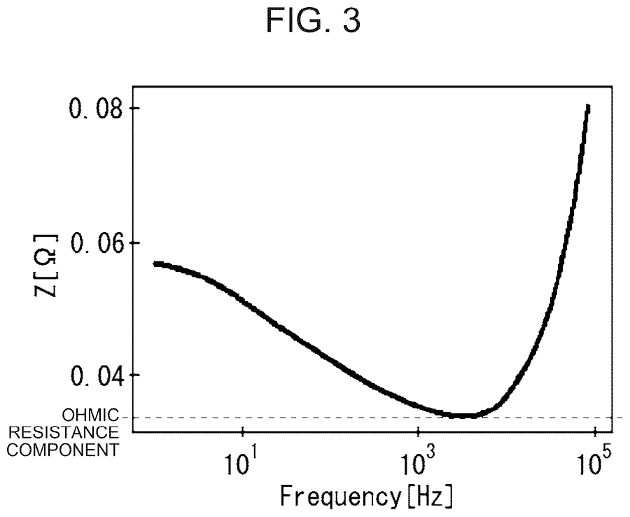

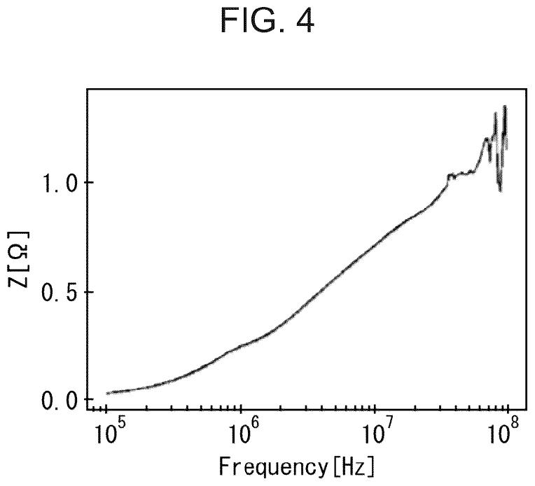

FIG. 3 and FIG. 4 are views indicating a relationship between a frequency of an alternating current signal to be supplied to the secondary battery 20 and the real part of the alternating current impedance detected from the secondary battery 20. FIG. 3 indicates a value of the real part Z of the alternating current impedance when an alternating current signal from 1 kHz to 100 kHz is supplied to the secondary battery 20. FIG. 4 indicates a value of the real part Z of the alternating current impedance when an alternating current signal from 100 kHz to 100 MHz is supplied to the secondary battery 20.

As indicated in FIG. 3, when the alternating current signal around 1 kHz is supplied to the secondary battery 20, the value of the real part Z of the alternating current impedance indicates a minimum value. An impedance component in this event represents an ohmic resistance component. Further, as indicated in FIG. 3 and FIG. 4, as a frequency of the alternating current signal to be supplied to the secondary battery 20 becomes higher, the value of the real part Z of the alternating current impedance becomes greater because flow of currents concentrate on an electrode surface of each cell by a skin effect.

Thus, the high-frequency signal supply unit 11 supplies such a high-frequency alternating current signal (that is, a high-frequency signal) that a sufficiently high value of the real part Z of the alternating current impedance compared to the ohmic resistance component is detected, to the secondary battery 20. For example, the high-frequency signal supply unit 11 supplies a high-frequency signal equal to or higher than 0.1 MHz to the secondary battery 20. In the examples in FIG. 3 and FIG. 4, the high-frequency signal supply unit 11 supplies a high-frequency signal equal to or higher than 0.5 MHz to the secondary battery 20. As a result of this, currents of the high-frequency signal flow on an electrode surface (Li precipitation region) of each battery cell of the secondary battery 20 by a skin effect. This enables the impedance detection unit 12 to detect the real part Z of the alternating current impedance in accordance with the amount of Li precipitation.

The determination unit 13 determines whether Li has been precipitated in the first battery cell of the secondary battery 20 from the value of the real part Z of the alternating current impedance detected by the impedance detection unit 12. More specifically, the determination unit 13 determines whether Li has been precipitated in the secondary battery 20 based on a difference between a current value of the real part Z of the alternating current impedance detected by the impedance detection unit 12 and an initial value of the real part Z of the alternating current impedance of the secondary battery 20. Information regarding the initial value of the real part Z of the alternating current impedance of the secondary battery 20 to be managed is stored in, for example, the storage unit 15. The determination unit 13 may, for example, subtract the value of the real part Z of the alternating current impedance from the initial value, and when the subtraction result is greater than a threshold, determine that Li has been precipitated in the secondary battery 20. The determination unit 13 may perform other kinds of calculation (such as, for example, calculation of a ratio) different from the subtraction of the real part Z of the alternating current impedance from the initial value.

Note that the storage unit 15 may store information regarding initial values of real parts Z of alternating current impedance of various kinds of secondary batteries. The initial values of the real parts Z of the alternating current impedance may be updated upon operation of the secondary battery 20. The storage unit 15 may include a memory such as a random access memory (RAM).

The control unit 14 controls allowable charging electric power Pa for the secondary battery 20 based on the determination result by the determination unit 13. For example, when it is determined that Li has not been precipitated, progress of Li precipitation is suppressed, and thus, the control unit 14 performs control to maintain the allowable charging electric power Pa as is or increase the allowable charging electric power Pa. When it is determined that Li has been precipitated, it is necessary to suppress progress of Li precipitation, and thus, the control unit 14 performs control to decrease the allowable charging electric power Pa. Note that the control unit 14 may switch the allowable charging electric power Pa stepwise in accordance with the determination result as to whether Li has been precipitated.

This enables the battery management device 10 according to the present disclosure to set to the secondary battery 20, the allowable charging electric power Pa as high as possible with which charging can be efficiently performed in a charging period as short as possible while suppressing Li precipitation. In other words, the battery management device 10 according to the present disclosure can set an appropriate value for the allowable charging electric power Pa for the secondary battery 20 in accordance with the amount of Li precipitation without setting the allowable charging electric power Pa at excessively low, so that it is possible to implement efficient charging of the secondary battery 20.

Functions of the determination unit 13 and the control unit 14 may be implemented by, for example, programs being loaded to the memory and executed by the processor. Alternatively, the determination unit 13 and the control unit 14 may be implemented with hardware such as a semiconductor chip and an electronic circuit. At least part of the high-frequency signal supply unit 11 and the impedance detection unit 12 may be constituted with an electronic circuit such as a resonance circuit and a peak hold circuit. However, part of the functions of the high-frequency signal supply unit 11 and the impedance detection unit 12 may be executed by the processor. For example, the processor may transmit a control signal to an electronic circuit that constitutes the high-frequency signal supply unit 11 and the impedance detection unit 12 to thereby apply the high-frequency signal to the first battery cell and detect the real part of the alternating current impedance of the first battery cell.

When Li is precipitated in the secondary battery 20, it is considered that Li is precipitated sequentially from a battery cell with a relatively lower battery temperature. The battery management device 10 controls the allowable charging electric power Pa based on the real part Z of the alternating current impedance of the first battery cell, so that it is possible to reduce the number of circuits and cost required for efficient charging.

### Operation of Battery Management Device 10

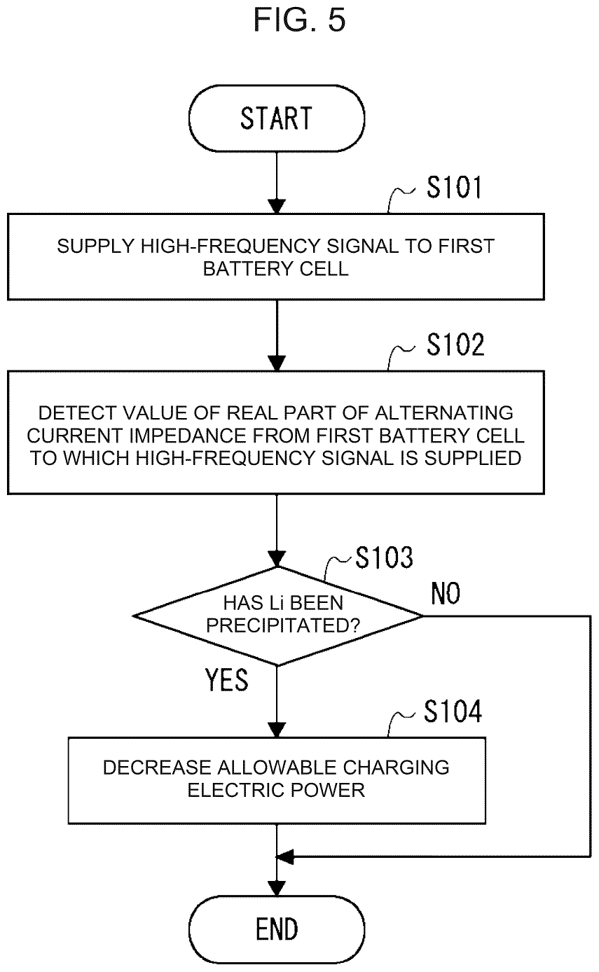

Subsequently, an example of operation of the battery management device 10 will be described using FIG. 5. FIG. 5 is a flowchart indicating the operation of the battery management device 10.

First, the battery management device 10 supplies a high-frequency alternating current signal (high-frequency signal) that is too high for diffusion, response, and movement of lithium ions to follow in each battery cell, to the first battery cell of the secondary battery 20 (step S101). For example, the battery management device 10 supplies a high-frequency signal equal to or higher than 0.1 MHz to the secondary battery 20. Then, the battery management device 10 detects a value of the real part Z of the alternating current impedance from the secondary battery 20 to which the high-frequency signal is supplied (step S102).

Then, the battery management device 10 determines whether Li has been precipitated in the first battery cell of the secondary battery 20 from the detected value of the real part Z of the alternating current impedance (step S103). Basically, the battery management device 10 determines that Li has been precipitated in the first battery cell when the detected value of the real part Z of the alternating current impedance is smaller than the initial value.

When it is determined that Li has been precipitated in the first battery cell (step S103: Yes), it is necessary to suppress progress of the Li precipitation, and thus, the battery management device 10 performs control to decrease the allowable charging electric power Pa (step S104). When it is determined that Li has not been precipitated in the first battery cell (step S103: No), the progress of the Li precipitation is suppressed, and thus, the battery management device 10 maintains the allowable charging electric power Pa as is. Alternatively, the battery management device 10 may perform control to increase the allowable charging electric power Pa.

In this manner, the battery management device 10 according to the present disclosure can set to the secondary battery 20, the allowable charging electric power Pa as high as possible with which charging can be efficiently performed in a charging period as short as possible while suppressing Li precipitation. The battery management device 10 can perform charging control based on the real part Z of the alternating current impedance of one battery cell, so that it is possible to reduce processing of detecting the real part Z of the alternating current impedance of each of the plurality of battery cells.

### First Modification of First Embodiment

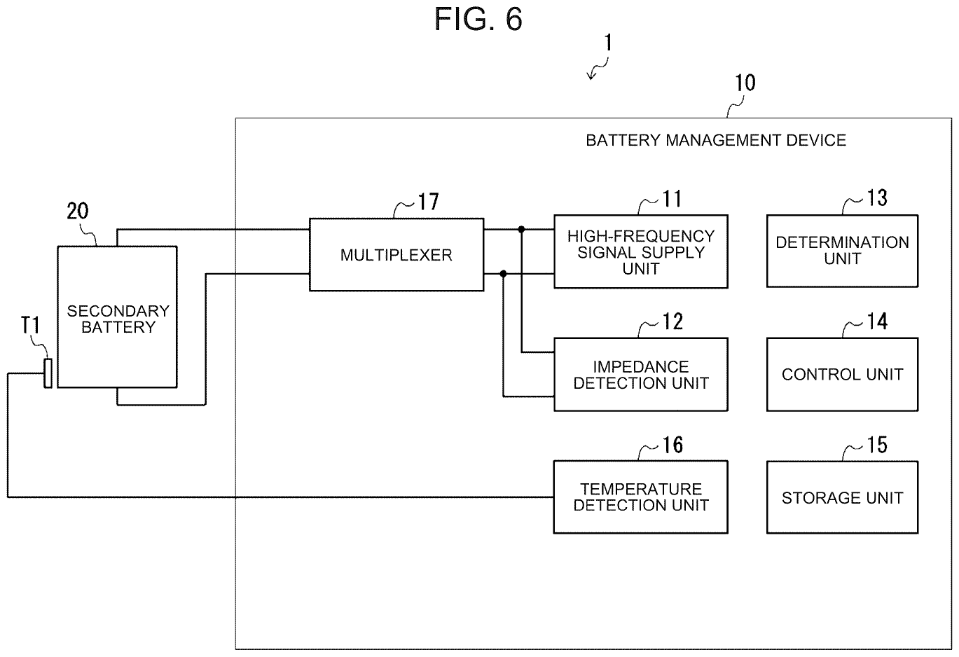

FIG. 6 is a block diagram illustrating a configuration example of the battery management system 1 according to a first modification of the first embodiment. Comparing FIG. 1 and FIG. 6, the battery management device 10 illustrated in FIG. 6 further includes a temperature detection unit 16 and a multiplexer 17. Functions of the temperature detection unit 16 may be implemented by the processor executing a program or may be implemented by hardware such as a semiconductor chip and an electronic circuit.

The temperature detection unit 16 detects the battery temperature of each battery cell of the secondary battery 20. For example, the temperature detection unit 16 detects battery temperatures of one or more battery cells among the plurality of battery cells constituting the secondary battery 20 using one or more thermistors T1. Further, the temperature detection unit 16 calculates a resistance value of each of the plurality of battery cells from a cell voltage of each of the plurality of battery cells. Then, the temperature detection unit 16 calculates a difference of an amount of heat generation of each of the plurality of battery cells from an amount of heat generation of the battery cell to which the thermistor T1 is attached from a difference between the calculated resistance value of the plurality of battery cells and the resistance value of the battery cell to which the thermistor T1 is attached, and estimates the battery temperature of each of the plurality of battery cells from the calculation result. The thermistor T1 may be attached to each of the plurality of battery cells, and the temperature detection unit 16 may detect the battery temperature measured using the thermistor T1.

The temperature detection unit 16 sets the battery cell with a low battery temperature as the first battery cell based on the battery temperature of each battery cell. The first battery cell may be a battery cell with a relatively low battery temperature among the battery cells to which the thermistors T1 are attached. The thermistors T1 do not have to be attached to all the battery cells constituting the secondary battery 20. The temperature detection unit 16 may output a selection signal corresponding to the battery cell set as the first battery cell to the multiplexer 17.

The multiplexer 17 switches the battery cell to be connected to the high-frequency signal supply unit 11 and the impedance detection unit 12 among the plurality of battery cells constituting the secondary battery 20. The plurality of battery cells in the secondary battery 20 may be connected in series to each other or may be connected in parallel to each other. The plurality of battery cells may be connected in series and in parallel. The multiplexer 17 may connect the battery cell in accordance with the selection signal received from the temperature detection unit 16, that is, the first battery cell to the high-frequency signal supply unit 11 and the impedance detection unit 12. Note that when the high-frequency signal supply unit 11 is configured to supply a high-frequency signal to a plurality of battery cells, only the battery cell to be connected to the impedance detection unit 12 may be switched.

Referring to FIG. 5 again, the battery management device 10 according to the modification of the first embodiment, for example, sets the first battery cell based on the battery temperature of each battery cell before step S101 and switches the connection destination of the high-frequency signal supply unit 11 and the impedance detection unit 12.

According to the modification of the first embodiment, it is possible to appropriately set the first battery cell and improve determination accuracy as to whether Li has been precipitated.

### Second Embodiment

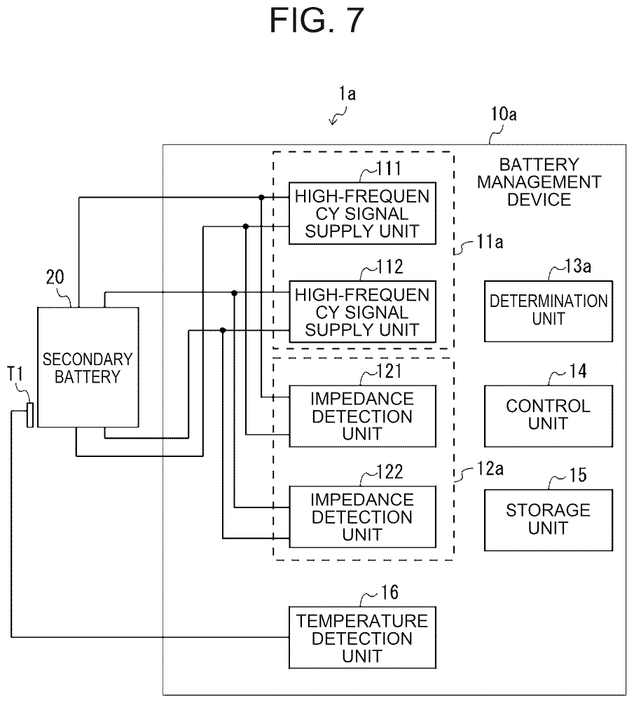

FIG. 7 is a block diagram illustrating a configuration example of a battery management system 1a according to a second embodiment. Comparing FIG. 1 and FIG. 7, the battery management device 10 is replaced with a battery management device 10a. In the battery management device 10a, the high-frequency signal supply unit 11 is replaced with a high-frequency signal supply unit 11a, the impedance detection unit 12 is replaced with an impedance detection unit 12a, and the determination unit 13 is replaced with a determination unit 13a. Further, the battery management device 10a includes the temperature detection unit 16 that has already been described with reference to FIG. 6.

A plurality of battery cells constituting the secondary battery 20 includes the first battery cell described above, and a second battery cell with a higher battery temperature than the battery temperature of the first battery cell. The first battery cell and the second battery cell may be set in advance in accordance with results of simulation, experiment, and the like. Further, the first battery cell and the second battery cell may be set based on the measurement result of the thermistor T1.

The high-frequency signal supply unit 11a includes high-frequency signal supply units 111 and 112. The high-frequency signal supply unit 111 applies a high-frequency signal to the first battery cell, and the high-frequency signal supply unit 112 applies a high-frequency signal to the second battery cell. Note that one high-frequency signal supply unit 11 may be configured to supply the high-frequency signal to both the first battery cell and the second battery cell.

The impedance detection unit 12a includes impedance detection units 121 and 122. The impedance detection unit 121 detects a real part Z1 of alternating current impedance of the first battery cell, and the impedance detection unit 122 detects a real part Z2 of alternating current impedance of the second battery cell.

The determination unit 13a determines whether Li has been precipitated in the secondary battery 20 based on the real part Z1 of the alternating current impedance of the first battery cell and the real part Z2 of the alternating current impedance of the second battery cell. Flow of the determination method by the determination unit 13a will be described below.

After the real part Z1 of the alternating current impedance of the first battery cell is detected, the determination unit 13a stores a degree of change (for example, a degree of decrease, a degree of increase) of the real part Z1 of the alternating current impedance from the initial value in the storage unit 15 in association with the battery temperature of the first battery cell. This enables the determination unit 13a to generate first impedance information indicating the degree of change (also referred to as a first degree of change) of the real part Z1 of the alternating current impedance for each battery temperature of the first battery cell. Using a similar method, the determination unit 13a can generate second impedance information indicating a degree of change (also referred to as a second degree of change) of the real part Z2 of the alternating current impedance from the initial value for each battery temperature of the second battery cell. When the values of the real parts Z1 and Z2 of the alternating current impedance are smaller than the initial values, absolute values of the first and the second degrees of change are also referred to as first and second degrees of decrease, respectively. When the values of the real parts Z1 and Z2 of the alternating current impedance are greater than the initial values, the first and the second degrees of change are also referred to as first and second degrees of increase, respectively.

The initial value of the real part Z1 of the alternating current impedance may be the same as or different from the initial value of the real part Z2 of the alternating current impedance. The initial values of the real parts Z1 and Z2 of the alternating current impedance may be stored in the storage unit 15. The initial values may be stored for each battery temperature, or initial values not depending on the battery temperature may be stored. The values of the real parts Z1 and Z2 of the alternating current impedance may be greater or smaller than the initial values not depending on the battery temperature.

The determination unit 13a determines whether Li has been precipitated in the secondary battery 20 based on the first degree of change and the second degree of change detected at the same battery temperature with reference to the first impedance information and the second impedance information. The determination unit 13a may specifically determine that Li has been precipitated in the secondary battery 20 when the first degree of decrease is larger than the second degree of decrease or when the first degree of increase is smaller than the second degree of increase. The determination unit 13a may determine that Li has been precipitated when the first degree of decrease at one battery temperature is larger than the second degree of decrease or when the first degree of increase at the one battery temperature is smaller than the second degree of increase. The determination unit 13a may determine that Li has been precipitated when there is tendency that the first degree of decrease becomes larger than the second degree of decrease at a plurality of battery temperatures or when there is tendency that the first degree of increase becomes smaller than the second degree of increase at the plurality of battery temperatures. A case where the first degree of decrease is larger than the second degree of decrease includes a case where the first degree of decrease is larger than the second degree of decrease by an amount equal to or greater than a threshold. A case where the first degree of increase is smaller than the second degree of increase includes a case where the second degree of increase is larger than the first degree of increase by an amount equal to or greater than a threshold.

To supplement the above, while there is a case where a likelihood of Li precipitation may depend on a state of the secondary battery 20, the battery management device 10a improves determination accuracy as to whether Li has been precipitated by comparing the real parts Z1 and Z2 of the alternating current impedance. Further, it is possible to reduce influence of an error of the impedance detection unit 12. However, the values of Z1 and Z2 of the alternating current impedance also depend on the battery temperature, and thus, the determination unit 13a performs determination based on the real parts Z1 and Z2 of the alternating current impedance at the same battery temperature. While the battery temperature of the first battery cell is lower than the battery temperature of the second battery cell at one time point, the battery temperatures of the first battery cell and the second battery cell temporally change during operation of the secondary battery 20, and thus, there is a case where the battery temperatures of the first battery cell and the second battery cell become the same at different time points.

The control unit 14 controls the allowable charging electric power Pa for the secondary battery 20 based on the determination result by the determination unit 13a in a similar manner to the first embodiment.

The battery management device 10a can improve determination accuracy as to whether Li has been precipitated by using the real parts Z of the alternating current impedance of two battery cells. Further, when there are three or more battery cells that constitute the secondary battery 20, there is a possibility that the number of electronic circuits that constitute the impedance detection unit 12 can be reduced.

### Operation of Battery Management Device 10a

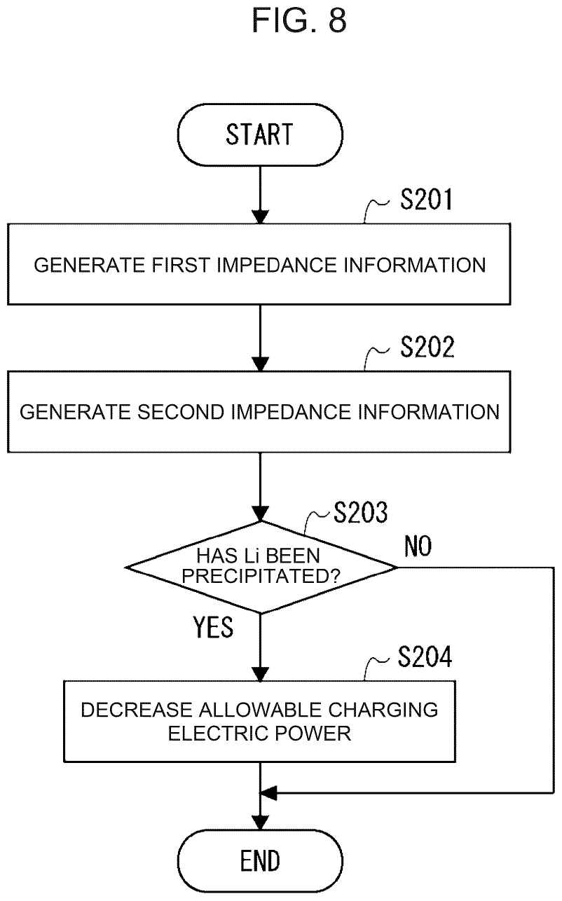

Subsequently, an example of operation of the battery management device 10a will be described using FIG. 8. FIG. 8 is a flowchart indicating the operation of the battery management device 10a.

First, the battery management device 10a generates the first impedance information based on the value of the real part Z1 of the alternating current impedance of the first battery cell (step S201). In a similar manner, the battery management device 10a generates the second impedance information based on the real part Z2 of the alternating current impedance of the second battery cell (step S202). The order of step S201 and step S202 may be reverse.

Then, the battery management device 10a determines whether Li has been precipitated in the secondary battery 20 based on the first impedance information generated in step S201 and the second impedance information generated in step S202 (step S203). Step S204 is similar to step S104 in FIG. 5, and thus, description will be omitted.

In this manner, the battery management device 10 according to the present disclosure can improve determination accuracy as to whether Li has been precipitated and further improve charging efficiency of the secondary battery 20.

### First Modification of Second Embodiment

In a similar manner to the first modification of the first embodiment, the battery management device 10a may set the first battery cell and the second battery cell using the measurement result of the thermistor T1. The battery management device 10a may include both a multiplexer for switching the connection destination of the high-frequency signal supply unit 111 and the impedance detection unit 121 among the plurality of cells, and a multiplexer for switching the connection destination of the high-frequency signal supply unit 112 and the impedance detection unit 122 among the plurality of cells.

According to the first modification of the second embodiment, it is possible to appropriately set the first battery cell and the second battery cell and determine whether Li has been precipitated with high accuracy.

### Second Modification of Second Embodiment

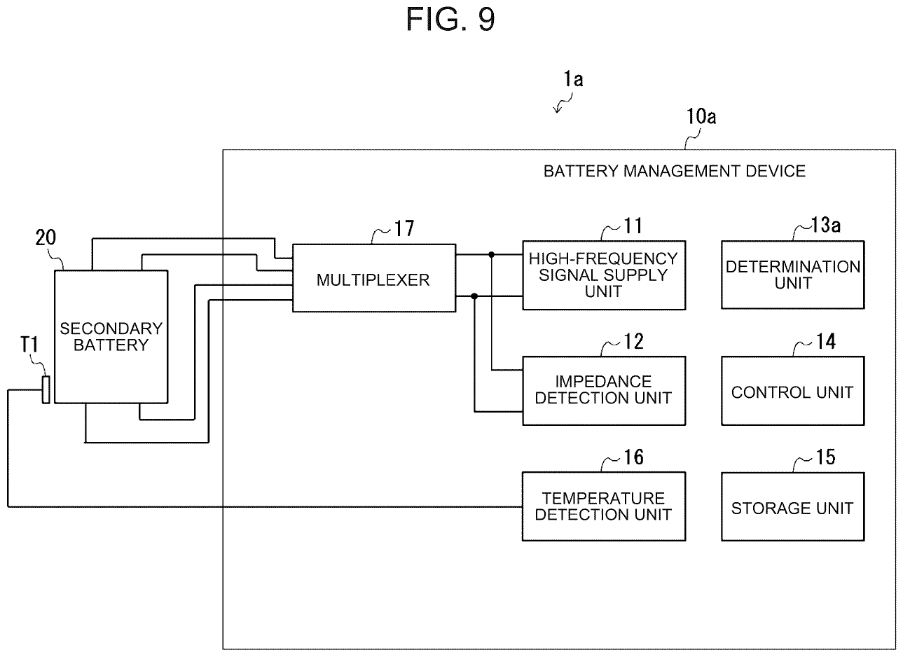

FIG. 9 is a block diagram illustrating a configuration example of a battery management system according to a second modification of the second embodiment. Comparing FIG. 7 and FIG. 9, the two high-frequency signal supply units 111 and 112 are replaced with one high-frequency signal supply unit 11, and the two impedance detection units 121 and 122 are replaced with one impedance detection unit 12. Further, the battery management device 10a illustrated in FIG. 9 further includes the multiplexer 17.

The multiplexer 17 switches the connection destination of the high-frequency signal supply unit 11 and the impedance detection unit 12 between the first battery cell and the second battery cell. When the high-frequency signal supply unit 11 is configured to apply a high-frequency signal to a plurality of battery cells, only the connection destination of the impedance detection unit 12 may be switched.

In the second modification of the second embodiment, it is possible to reduce the number of electronic circuits that constitute the high-frequency signal supply unit 11 and the impedance detection unit 12 and improve determination accuracy as to whether Li has been precipitated.

Further, in the present disclosure, part or all of the processing of the battery management device 10 can be implemented by causing a central processing unit (CPU) to execute a computer program.

The above-described program includes commands (or software codes) for causing a computer to perform one or more functions described in the embodiments when the commands are loaded to the computer. The program may be stored in a non-transitory computer-readable medium or a tangible storage medium. As an example and not as a limitation, the computer-readable medium or the tangible storage medium includes a random-access memory (RAM), a read-only memory (ROM), a flash memory, a solid-state drive (SSD), or other memory technologies, a CD-ROM, a digital versatile disc (DVD), a Blu-ray (registered trademark) disc, or other optical disc storages, and a magnetic cassette, a magnetic tape, a magnetic disk storage, or other magnetic storage devices. The program may be transmitted on a transitory computer-readable medium or a communication medium. As an example and not as a limitation, the transitory computer-readable medium or the communication medium includes electrical, optical, or acoustic propagation signals or propagation signals in other formats.

While the embodiments of the present disclosure have been described above, the present disclosure is not limited to the above-described embodiments. Various changes that can be understood by a person skilled in the art can be made in the configuration and details of the present disclosure within the scope of the present disclosure. Further, the embodiments can be combined as appropriate with other embodiments.

What is claimed is:

1. A battery management device comprising:
a high-frequency signal supply unit configured to apply a high-frequency signal having a frequency equal to or higher than 0.1 MHz to a first battery cell having a low battery temperature among a plurality of battery cells constituting a lithium-ion secondary battery;
an impedance detection unit configured to detect a real part of alternating current impedance of the first battery cell to which the high-frequency signal is applied; and
a determination unit configured to determine whether Li has been precipitated in the lithium-ion secondary battery based on the real part of the alternating current impedance of the first battery cell.

2. The battery management device according to claim 1, wherein:
the high-frequency signal supply unit is configured to further apply the high-frequency signal to a second battery cell having a higher battery temperature than a battery temperature of the first battery cell among the plurality of battery cells;
the impedance detection unit is configured to further detect a real part of alternating current impedance of the second battery cell; and
the determination unit is configured to determine whether Li has been precipitated in the lithium-ion secondary battery based on the real part of the alternating current impedance of the first battery cell and the real part of the alternating current impedance of the second battery cell detected at the same battery temperature.

3. The battery management device according to claim 2, wherein the determination unit is configured to determine whether Li has been precipitated in the lithium-ion secondary battery based on a degree of change of the real part of the alternating current impedance of the first battery cell at a certain battery temperature and a degree of change of the real part of the alternating current impedance of the second battery cell at the certain battery temperature.

4. The battery management device according to claim 2, further comprising a multiplexer configured to switch a connection destination of an electronic circuit that functions as the impedance detection unit between the first battery cell and the second battery cell.

5. The battery management device according to claim 1, further comprising a temperature detection unit configured to detect a battery temperature of each of the plurality of battery cells and set the first battery cell based on a detection result.

6. A battery management method comprising:
applying a high-frequency signal having a frequency equal to or higher than 0.1 MHz to a first battery cell having a low battery temperature among a plurality of battery cells constituting a lithium-ion secondary battery;
detecting a real part of alternating current impedance of the first battery cell to which the high-frequency signal is applied; and
determining whether Li has been precipitated in the lithium-ion secondary battery based on the real part of the alternating current impedance of the first battery cell.

7. A non-transitory storage medium storing instructions that are executable by a computer and that cause the computer to perform functions comprising:
applying a high-frequency signal having a frequency equal to or higher than 0.1 MHz to a first battery cell having a low battery temperature among a plurality of battery cells constituting a lithium-ion secondary battery;
detecting a real part of alternating current impedance of the first battery cell to which the high-frequency signal is applied; and
determining whether Li has been precipitated in the lithium-ion secondary battery based on the real part of the alternating current impedance of the first battery cell.
